(19) United States
(12) Patent Application Publication
(10) Pub. No.: US 2022/0137658 A1
(43) Pub. Date: May 5, 2022

(54) SEMICONDUCTOR DEVICE WITH REFERENCE VOLTAGE CIRCUIT

(71) Applicant: ABLIC Inc., Tokyo (JP)

(72) Inventors: Takeshi KOYAMA, Tokyo (JP); Hisashi HASEGAWA, Tokyo (JP); Shinjiro KATO, Tokyo (JP); Kohei KAWABATA, Tokyo (JP)

(21) Appl. No.: 17/511,947

(22) Filed: Oct. 27, 2021

(30) Foreign Application Priority Data
Oct. 30, 2020 (JP) 2020-182403
Mar. 18, 2021 (JP) 2021-044195

(51) Int. Cl. G05F 3/24; H01L 27/088; H01L 29/49

(52) U.S. Cl. CPC G05F 3/24; H01L 29/4908; H01L 27/0883

(57) ABSTRACT

Provided is a semiconductor device with a reference voltage circuit including an enhancement type transistor having P-type polycrystalline silicon as a first gate electrode, and a depletion type transistor having N-type polycrystalline silicon as a second gate electrode, in which the enhancement type transistor has an impermeable film that is locally provided to cover the first gate electrode via an interlayer insulating film disposed on the first gate electrode, and a nitride film that has an opening portion which is provided larger than the first gate electrode and smaller than the impermeable film, and is provided to cover a periphery of the impermeable film, and the depletion type transistor has a nitride film that is directly provided on an interlayer insulating film disposed on the second gate electrode and covers the depletion type transistor without a gap.

### RELATED APPLICATIONS

This application claims priority to Japanese Patent Application No. 2020-182403, filed on Oct. 30, 2020, and Japanese Patent Application No. 2021-044195, filed Mar. 18, 2021, the entire contents of which are incorporation herein by reference.

### BACKGROUND OF THE INVENTION

### 1. Field of the Invention

The present invention relates to a semiconductor device with a reference voltage circuit having an N-type MOS transistor with a P-type gate electrode.

### 2. Description of the Related Art

A reference voltage circuit that outputs a constant voltage with respect to fluctuations in a power supply voltage can be configured by using two N-type MOS transistors (enhancement type and depletion type).

Regarding the reference voltage circuit, it is often used to suppress fluctuations in output voltage due to temperature. As shown in JP-A-2008-293409, there is the following method: in two N-type MOS transistors (enhancement type and depletion type) constituting a reference voltage circuit (Vref circuit), while the same impurity concentration in channel regions is kept, for a conductivity type of polycrystalline silicon configuring gate electrodes and having the same N-type conductivity in the conventional, polycrystalline silicon whose conductivity type is a P-type is used only for the gate electrode of the enhancement type transistor. By using a difference in work function caused by the difference in conductivity type of the gate electrodes, a difference in threshold voltage (Vth) between an enhancement type MOS transistor having polycrystalline silicon of P-type conductivity as a gate electrode and a depletion type MOS transistor having polycrystalline silicon of N-type conductivity as a gate electrode is provided to generate a reference voltage.

In this case, since the impurity concentrations in the channel regions are the same, an effect of a temperature change on the threshold voltages of both transistors is also the same, so that it is possible to suppress fluctuations in reference voltage obtained from the difference between the threshold values of both transistors.

Hereinafter, a gate electrode composed of polycrystalline silicon having P-type conductivity is referred to as a P-type gate electrode, and a gate electrode composed of polycrystalline silicon having N-type conductivity is referred to as an N-type gate electrode; a MOS transistor having polycrystalline silicon of P-type conductivity as a gate electrode is referred to as a P-type gate electrode MOS transistor, and a MOS transistor having polycrystalline silicon of N-type conductivity as a gate electrode is referred to as an N-type gate electrode MOS transistor. A Vref circuit configured with the P-type gate electrode MOS transistor and the N-type gate electrode MOS transistor is referred to as a Vref circuit using gates having different polarities.

### SUMMARY OF THE INVENTION

In order to evaluate reliability of the Vref circuit using the gates having different polarities, in a high temperature storage (HTS) test which is one of accelerated tests that are conducted under stricter environmental conditions than in actual use, it has been found that the P-type gate electrode MOS transistor may cause a threshold voltage shift. The shift causes the reference voltage to fluctuate, leading to a shift in characteristics of ICs in a long-term reliability test. One of the causes of the threshold voltage shift is the influence of hydrogen. Note that although the amount of shift of the threshold voltage is as small as several millivolts, there are applications where the intended performance is a high degree of stability of the reference voltage obtained from the threshold voltage.

An object of the present invention is to provide a semiconductor device with a reference voltage circuit by using a transistor structure capable of suppressing the shift of the threshold voltage generated in the P-type gate electrode MOS transistor in the high temperature storage test.

An aspect of the present invention provides a semiconductor device with a reference voltage circuit having the following configuration. Specifically, the semiconductor device with a reference voltage circuit includes an enhancement type MOS transistor having polycrystalline silicon of P-type conductivity, as a first gate electrode; and a depletion type MOS transistor having polycrystalline silicon of N-type conductivity, as a second gate electrode, in which the enhancement type MOS transistor has an impermeable film that is locally provided to cover the first gate electrode via an interlayer insulating film disposed on the first gate electrode, and a nitride film that has an opening portion which is provided larger than the first gate electrode in a plan view and smaller than the impermeable film, and is provided to cover a periphery of the impermeable film, and the depletion type MOS transistor has a nitride film that is directly provided on an interlayer insulating film disposed on the second gate electrode and covers the depletion type MOS transistor without a gap in a plan view.

In a P-type gate electrode MOS transistor, a semiconductor device with a reference voltage circuit according to the present invention suppresses the diffusion of hydrogen and suppresses the fluctuation of an interface states due to leaving at a high temperature by removing a nitride film, which is a protective film that serves as a source of hydrogen diffusion which is a factor that causes a threshold voltage shift in a high temperature storage test, from an upper part of the P-type gate electrode. It is possible to easily suppress fluctuations in IC characteristics without changing a process. Since a range from which the nitride film is removed is local and the impermeable film is under the opening portion from which the nitride film is removed, entering of water is sufficiently suppressed and reliability does not easily decrease.

### BRIEF DESCRIPTION OF THE DRAWINGS

FIG. 1 is a plan view of a semiconductor device with a reference voltage circuit according to a first embodiment of the present invention.

FIG. 2 is a schematic cross-sectional view taken along a cutting line A in FIG. 1.

FIG. 3 is a schematic cross-sectional view taken along a cutting line B in FIG. 1.

FIG. 4 is an equivalent circuit view of a reference voltage circuit according to a first embodiment.

FIG. 5 is a comparison view of an amount of shift in a high temperature storage test.

FIG. 6 is a schematic cross-sectional view of a semiconductor device with a reference voltage circuit according to a second embodiment of the present invention.

FIG. 7 is a schematic cross-sectional view of a semiconductor device with a reference voltage circuit according to a third embodiment of the present invention.

### DETAILED DESCRIPTION OF THE PREFERRED EMBODIMENTS

Hereinafter, embodiments of the present invention will be described with reference to the drawings.

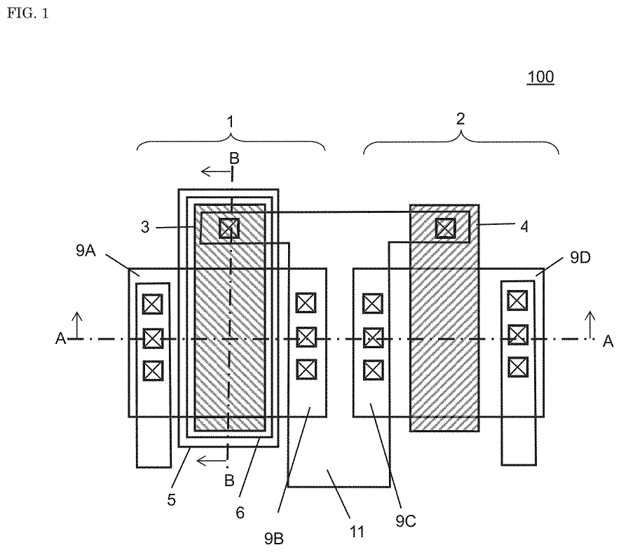

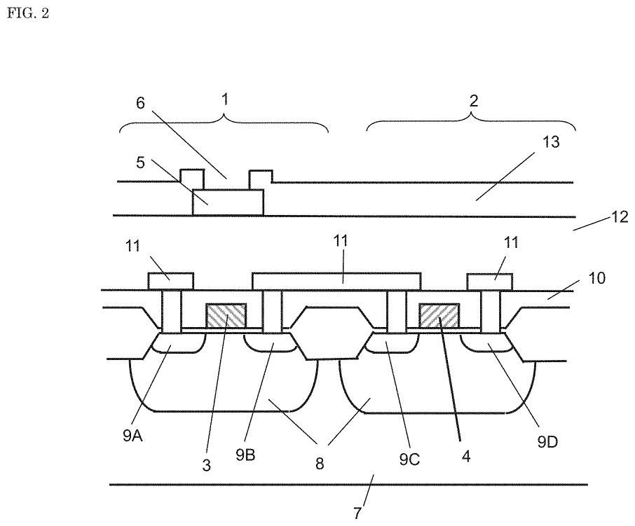

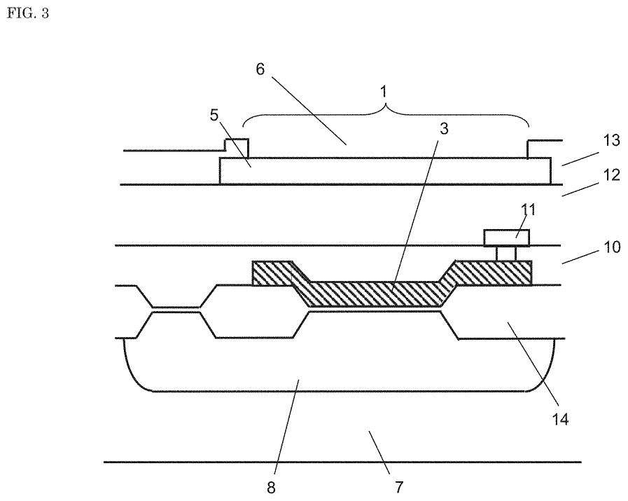

FIG. 1 is a plan view of a semiconductor device with a reference voltage circuit according to a first embodiment of the present invention. FIG. 2 is a schematic cross-sectional view taken along a cutting line A in FIG. 1, and FIG. 3 is a schematic cross-sectional view taken along a cutting line B in FIG. 1.

As illustrated in FIG. 1, a semiconductor device 100 with a reference voltage circuit has an enhancement type MOS transistor 1 and a depletion type MOS transistor 2. Conductivity types of the enhancement type MOS transistor 1 and the depletion type MOS transistor 2 are both an N type and are sometimes called an N channel.

As illustrated in FIGS. 2 and 3, the enhancement type MOS transistor 1 is provided on a surface of a P-type well 8 disposed on an N-type substrate 7 and is provided with a source 9A and a drain 9B, both of which are N-type high concentration layers, interposing a P-type gate electrode 3 that is provided via a gate oxide film. An intermediate insulating film 10 is provided so as to cover the P-type gate electrode 3, and a first metal wiring 11 is provided on the intermediate insulating film 10. An interlayer insulating film 12 is provided so as to cover the first metal wiring 11, and an impermeable film 5 is locally disposed thereon so as to cover the P-type gate electrode 3. The impermeable film 5 is covered with a final protective film 13 disposed on the interlayer insulating film 12 on the outside from the periphery of an opening portion 6, but the opening portion 6 which is provided on an upper surface of the impermeable film 5 is not covered with the final protective film 13. The final protective film 13 has the opening portion 6 on the impermeable film 5 to expose the surface of the impermeable film 5.

As can be seen from FIG. 1, in a plan view, the impermeable film 5 covers the entire surface of the P-type gate electrode 3, so that the impermeable film 5 is larger than the P-type gate electrode 3. The opening portion 6 is provided larger than the P-type gate electrode 3 so as to include the entire surface of the P-type gate electrode 3 inside, but since the opening portion 6 is provided inside the impermeable film 5, the opening portion 6 is smaller than the impermeable film 5.

As illustrated in FIG. 2, the depletion type MOS transistor 2 is provided on a surface of another P-type well 8, which is different from the P-type well 8 provided with the enhancement type MOS transistor 1 and disposed on the N-type substrate 7, and is provided with a source 9C and a drain 9D, both of which are N-type high concentration layers, interposing an N-type gate electrode 4 provided via a gate oxide film. An intermediate insulating film 10 is provided so as to cover the N-type gate electrode 4, and a first metal wiring 11 is provided on the intermediate insulating film 10. The interlayer insulating film 12 is provided so as to cover the first metal wiring 11, and the entire surface is covered with the final protective film 13 disposed on the interlayer insulating film 12. Since the final protective film 13 that covers the depletion type MOS transistor 2 is not provided with an opening portion 6, the entire surface of the depletion type MOS transistor 2 is covered with the final protective film 13 without a gap.

As illustrated in FIG. 1, the drain 9B of the enhancement type MOS transistor 1 is connected to the source 9C of the depletion type MOS transistor 2 through the first metal wiring 11. Because of the same metal wiring, the P-type gate electrode 3 of the enhancement type MOS transistor 1 and the N-type gate electrode 4 of the depletion type MOS transistor 2 are also connected to have the same potential. Normally, the source 9A of the enhancement type MOS transistor 1 is connected to a wiring of a ground potential, and the drain 9D of the depletion type MOS transistor 2 is connected to a wiring of a power supply potential through the first metal wiring 11.

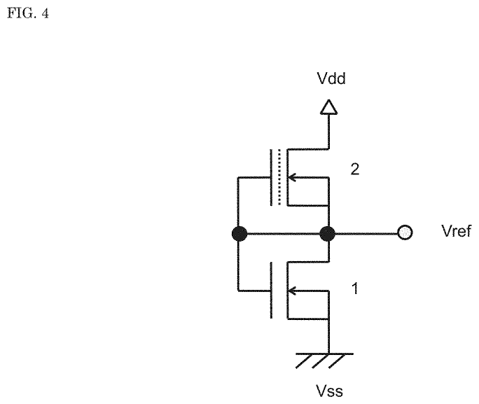

FIG. 4 is an equivalent circuit view illustrating a portion of the reference voltage circuit of the semiconductor device provided with the reference voltage circuit described with reference to FIGS. 1 to 3. The enhancement type MOS transistor 1 and the depletion type MOS transistor 2 connected in series are included therein, the source of the enhancement type MOS transistor 1 is connected to the ground potential V_{SS}, and the drain of the depletion type MOS transistor 2 is connected to the power supply potential V_{DD}. A reference voltage Vref is supplied from a connection point between the enhancement type MOS transistor 1 and the depletion type MOS transistor 2.

Next, a method of manufacturing the semiconductor device with the reference voltage circuit will be described. The enhancement type MOS transistor and the depletion type MOS transistor constituting the reference voltage circuit are provided in the vicinity of the surface of the P-type wells which are formed separately and spaced from each other in the N-type silicon substrate or the N-type well, respectively. After an isolation region is formed by using LOCOS or STI, a gate oxide film is formed, and a polycrystalline silicon film to be a gate electrode is deposited. After forming the polycrystalline silicon film with a thickness of 100 nm to 400 nm, the ion implantation of impurities is performed in the gate electrode region to be the enhancement type MOS transistor such that BF₂ is ion-implanted, for example, to form the P-type polycrystalline silicon, and performed in the gate electrode region to be the depletion type MOS transistor such that phosphorus is ion-implanted, for example, to form the N-type polycrystalline silicon. Thereafter, the polycrystalline silicon is patterned and processed to form the gate electrode.

Next, the intermediate insulating film covering the gate electrode is formed, a contact hole is formed, and then a metal film to be a first metal wiring layer is formed. Thereafter, the interlayer insulating film and a used number of multi-layer wiring layers are formed.

An impermeable layer is formed in a layer to be the uppermost layer of the multi-layer wiring, and in the patterning, at least the enhancement type MOS transistor constituting the reference voltage circuit is laid out so as to cover the gate electrode and patterned to form the impermeable film. It is also possible to dispose the impermeable film not only on the gate electrode of the enhancement type MOS transistor but also on the gate electrode of the depletion type MOS transistor.

As the impermeable layer, a metal wiring layer to be the uppermost layer can be used. Amorphous silicon formed by sputtering can also be used instead of metal.

After patterning the impermeable layer, the final protective film is formed. A structure of the final protective film may be a single-layer structure of a plasma nitride film or a two-layer structure of an oxide film and a plasma nitride film. Since hydrogen contained in the plasma nitride film is desorbed in the high temperature storage test and captured as an interface states, the final protective film of an area portion of the impermeable film disposed on the gate electrode of the on mentioned reference voltage circuit is etched and removed. By doing so, it is possible to prevent the diffusion of hydrogen from the plasma nitride film located directly on the P-type gate electrode, and it is possible to suppress the total amount of diffused hydrogen.

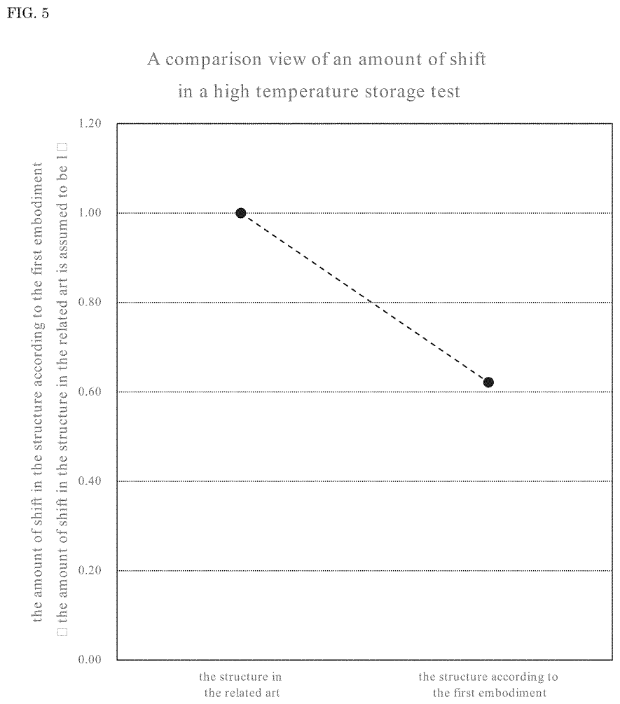

FIG. 5 is a view comparing the amount of shift shown in the high temperature storage test by the semiconductor device with the reference voltage circuit illustrated in FIGS. 1 to 4 with the amount of shift in the semiconductor device with the reference voltage circuit having a structure in the related art. Assuming that the amount of shift in the structure in the related art is 1, it can be seen that the amount of shift is reduced to 0.6 in the structure according to the first embodiment. From the comparison result, by disposing the impermeable film covering the P-type gate electrode 3 on the P-type gate electrode 3 of the enhancement type MOS transistor 1 and providing the opening portion from which the plasma nitride film that is the final protective film and is disposed on the impermeable film, is removed, it can be seen that it is possible to suppress the amount of shift of a threshold voltage in the high temperature storage test.

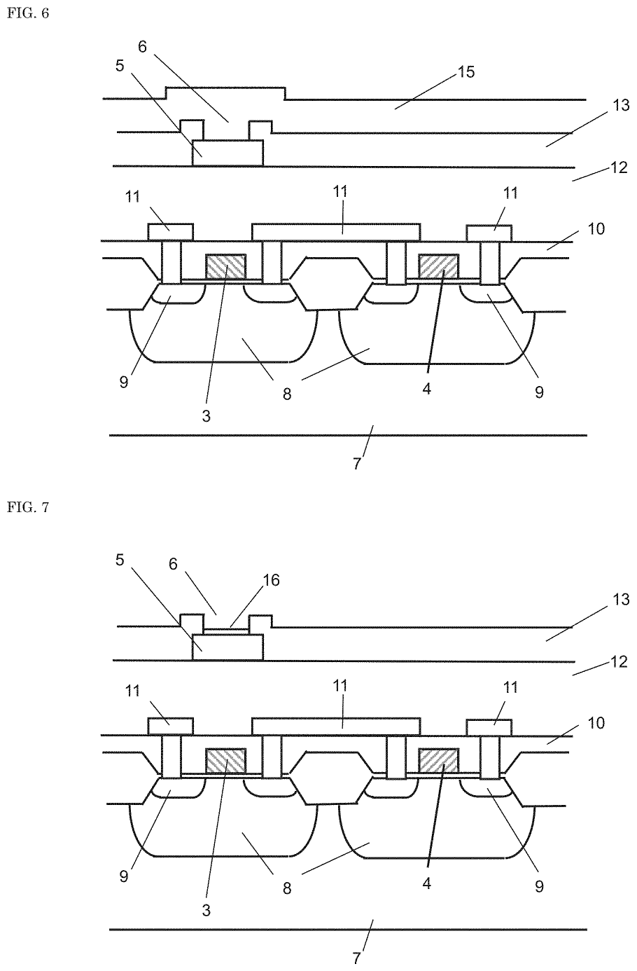

FIG. 6 is a schematic cross-sectional view of a semiconductor device with a reference voltage circuit according to a second embodiment of the present invention. The difference from the first embodiment is that it has a polyimide film 15 that covers the final protective film 13 disposed on the reference voltage circuit. Although the impermeable film 5 does not allow water to pass through, water may enter from the interface between the impermeable film 5 and the final protective film 13 in the periphery covered with the final protective film 13. Unlike hydrogen, water causes corrosion, and water is prevented from entering the semiconductor device. By disposing the polyimide film 15 provided on the final protective film 13 and covering the opening portion 6 located on the surface of the impermeable film 5 without a gap, a structure is configured such that the entering of water is suppressed from the interface between the impermeable film 5 and the final protective film 13. Since the polyimide is hydrophobic, it has the effect of delaying the entering of water.

FIG. 7 is a schematic cross-sectional view of a semiconductor device with a reference voltage circuit according to a third embodiment of the present invention. A difference from the first embodiment is that an oxide film having a corrosion resistance is provided on the surface of the impermeable film 5 which is the bottom of the opening portion 6. In regards to this, the use of the metal wiring layer or the use of amorphous silicon deposited by sputtering is mentioned as an example of the impermeable film 5 in the first embodiment. In the case of using the metal wiring layer, since there is the opening portion, there is a possibility that the impermeable film 5 using the metal wiring layer is corroded due to water or the like. In order to prevent the impermeable film 5 from being corroded, an oxide film 16 having a corrosion resistance is provided that covers, without a gap, at least the surface of the impermeable film 5 that is the bottom of the opening portion, so that it is possible to increase reliability of the semiconductor device against corrosion.

Examples of the oxide film 16 having a corrosion resistance include alumina (aluminum oxide: Al₂O₃) which is a metal oxide, and ceramics. The alumina can be formed by oxidation in an oxygen atmosphere or anodization in the case where the impermeable film 5 contains aluminum as a main component. The ceramic film can be formed by coating a thin film mainly made of a ceramic component. Since these oxides have a high corrosion resistance and can be formed at a relatively low temperature, these oxides can be used in the semiconductor device.

Note that the opening portion 6 uses to be longer than a first channel width at least in a first channel width direction and is provided so as to cover a first channel region. However, the opening portion 6 may be shorter than the first channel length in the first channel length direction and may be set inside the first channel region.

It is considered that fluctuations of the interface states due to leaving at a high temperature, is caused by the desorption of hydrogen due to an oxidation process that exists mainly in a place centered on an area with a low binding property between the gate insulating film and the semiconductor substrate. In particular, the area with the low binding property may be concentrated at a boundary between the isolation region and the channel region. The opening portion 6 sufficiently covers the area to suppress the entering of hydrogen from the nitride film which is a protective film, so that it is possible to suppress binding and desorption with the hydrogen that exists in the area having a low binding property.

On the other hand, a dangling bond of silicon generated, for example, by plasma etching processing at the time of forming the gate electrode is likely to be unevenly distributed at the boundary between the channel region and the source/drain region. The dangling bond is not terminated by hydrogen and acts as a fixed charge, which exhibits a tendency to increase the threshold voltage. By actively promoting the entering of hydrogen from the nitride film that is a protective film, and suppressing the rise in the threshold voltage and the variation of the threshold voltage, the reference voltage supplied by the reference voltage circuit can be stabilized. For that purpose, the opening portion 6 may be configured to be shorter than the first channel length in the first channel length direction and set inside the first channel region to promote the entering of hydrogen.

What is claimed is:

1. A semiconductor device with a reference voltage circuit comprising:
an enhancement type MOS transistor having a first channel region including a first channel length direction and a first channel width direction, and polycrystalline silicon having P-type conductivity that covers the first channel region and serves as a first gate electrode; and
a depletion type MOS transistor having a second channel region including a second channel length direction and a second channel width direction, and polycrystalline silicon having N-type conductivity that covers the second channel region and serves as a second gate electrode,
wherein the enhancement type MOS transistor has
an impermeable film that is locally provided to cover the first gate electrode via an interlayer insulating film disposed on the first gate electrode, and
a nitride film that has an opening portion which includes the first gate electrode in a plan view and is provided smaller than the impermeable film, and is provided to cover a periphery of the impermeable film, and
the depletion type MOS transistor has a nitride film that is directly provided on an interlayer insulating film disposed on the second gate electrode and covers the depletion type MOS transistor without a gap in a plan view.

2. The semiconductor device with a reference voltage circuit according to claim 1,
wherein the impermeable film is an uppermost wiring layer.

3. The semiconductor device with a reference voltage circuit according to claim 1,
wherein the impermeable film is amorphous silicon.

4. The semiconductor device with a reference voltage circuit according to claim 1, further comprising:
a polyimide film covering a final protective film,
wherein the polyimide film covers, without a gap, the opening portion that is provided in the final protective film and located on a surface of the impermeable film.

5. The semiconductor device with a reference voltage circuit according to claim 1, further comprising:
an oxide film having a corrosion resistance that covers a surface of the impermeable film without a gap.

6. The semiconductor device with a reference voltage circuit according to claim 1,
wherein the opening portion is longer than a first channel width in the first channel width direction and shorter than a first channel length in the first channel length direction.

7. The semiconductor device with a reference voltage circuit according to claim 6,
wherein the impermeable film is an uppermost wiring layer.

8. The semiconductor device with a reference voltage circuit according to claim 6,
wherein the impermeable film is amorphous silicon.

9. The semiconductor device with a reference voltage circuit according to claim 6, further comprising:
a polyimide film covering a final protective film,
wherein the polyimide film covers, without a gap, the opening portion that is provided in the final protective film and located on a surface of the impermeable film.

10. The semiconductor device with a reference voltage circuit according to claim 6, further comprising:
an oxide film having a corrosion resistance that covers a surface of the impermeable film without a gap.

11. A semiconductor device with a reference voltage circuit comprising:
an enhancement type MOS transistor having polycrystalline silicon of P-type conductivity, as a first gate electrode; and
a depletion type MOS transistor having polycrystalline silicon of N-type conductivity, as a second gate electrode,
wherein the enhancement type MOS transistor has
an impermeable film that is locally provided so as to cover the first gate electrode via an interlayer insulating film disposed on the first gate electrode, and
a nitride film that has an opening portion which is provided larger than the first gate electrode in a plan view and smaller than the impermeable film, and is provided so as to cover a periphery of the impermeable film, and
the depletion type MOS transistor has a nitride film that is directly provided on an interlayer insulating film disposed on the second gate electrode and covers the depletion type MOS transistor without a gap in a plan view.

12. The semiconductor device with a reference voltage circuit according to claim 11,
wherein the impermeable film is an uppermost wiring layer.

13. The semiconductor device with a reference voltage circuit according to claim 11,
wherein the impermeable film is amorphous silicon.

14. The semiconductor device with a reference voltage circuit according to claim 11, further comprising:
a polyimide film covering a final protective film,
wherein the polyimide film covers, without a gap, the opening portion that is provided in the final protective film and located on a surface of the impermeable film.

15. The semiconductor device with a reference voltage circuit according to claim 11, further comprising:
an oxide film having a corrosion resistance that covers a surface of the impermeable film without a gap.
